(19) United States
(12) Patent Application Publication
(10) Pub. No.: US 2024/0105574 A1
(43) Pub. Date: Mar. 28, 2024

(54) REDISTRIBUTION LAYERS, AND RELATED METHODS AND DEVICES

(71) Applicant: Micron Technology, Inc., Boise, ID (US)

(72) Inventors: M. Ataul Karim, Meridian, ID (US); David K. Ovard, Meridian, ID (US)

(21) Appl. No.: 17/936,278

(22) Filed: Sep. 28, 2022

(51) Int. Cl. H01L 23/498; H01L 21/48; H01L 23/14; H01L 23/15; H01L 23/522; H01L 23/528; H01L 23/538; H01L 25/065

(52) U.S. Cl. CPC H01L 23/49838; H01L 21/486; H01L 23/145; H01L 23/15; H01L 23/49833; H01L 23/5222; H01L 23/5226; H01L 23/5228; H01L 23/5283; H01L 23/5286; H01L 23/5385; H01L 23/5386; H01L 25/0655; H01L 24/16; H01L 2924/1431; H01L 2924/1433; H01L 2924/1434

(57) ABSTRACT

An interposer includes an upper surface for coupling to a chip, a lower surface for coupling to a package substrate, and redistribution layers between the upper surface and the lower surface and including routed conductive lines. A respective one of the routed conductive lines extend between a first location and a second location and includes two or more traces extending substantially in parallel between the first location and the second location. Related devices and methods are also described.

### TECHNICAL FIELD

The disclosure, in various embodiments, relates generally to the field of microelectronic devices and microelectronic-device design and fabrication. More specifically, the disclosure relates to redistribution layers, including, as examples, redistribution layers in interposers and redistribution layers of dies and to related methods, devices, and systems.

### BACKGROUND

Interposers including redistribution layers (RDLs) have been employed with semiconductor dies (which may be referred to in the art alternatively as “dies”) to reroute power, ground/bias, and/or signal connections from connection points (e.g., bond pads) of a die to a rearranged pattern of external connections, generally with a greater pitch (i.e., spacing) between the external connections of the RDLs in comparison to the pitch between connection points of the die. An RDL may include a single level of conductive traces between two levels of dielectric material, the traces coupled to an associated semiconductor die through contacts extending from the encapsulated traces to an exposed surface of the dielectric material of one level and optionally to surface traces, and to higher-level packaging through contacts extending from the traces to external connections (e.g., bumps, pillars, balls, or studs) on an exposed surface of the dielectric material of the other level. As complexity of semiconductor dies has increased while, at the same time overall dimensions of dies as well as critical dimensions of features of integrated circuitry of dies have decreased, it has become desirable to fabricate RDLs with multiple levels of traces, interposed dielectric layers, and interlayer contacts.

One particular application of RDLs is in fabrication of a so-called “fan-out wafer-level package” (FOWLP), where lateral dimensions of the RDL extend substantially beyond the periphery of a die to which the RDL is secured and operably coupled to provide an array of external connections at a substantially greater pitch than that of the bond pads of an associated semiconductor die. The term “wafer-level” is indicative of the fact that some such packages are formed conventionally on a large array of preformed RDLs or, alternatively, that the RDLs are formed on a large array of laterally-spaced semiconductor dies. The present and continued scaling, also characterized as miniaturization, of integrated circuitry and, concurrently, microelectronic devices, and associated thinning of dielectric materials, has reached a point where charge buildup and cross-talk may adversely affect performance of a microelectronic device.

### BRIEF DESCRIPTION OF THE DRAWINGS

FIG. 1A is a simplified, schematic, side, sectional, elevation view of a device, in accordance with embodiments of the disclosure.

FIG. 1B is a schematic, sectional, elevation view of the device shown in FIG. 1A, along a section line A-A shown in FIG. 1A.

FIG. 2A is a simplified, schematic, side, sectional, elevation view of a device, in accordance with additional embodiments of the disclosure.

FIG. 2B is a schematic, sectional, elevation view of the device shown in FIG. 2A, along a section line A-A shown in FIG. 2A.

FIG. 3 is a flowchart illustrating a formation method, in accordance with embodiments of the disclosure.

FIG. 4 is a simplified block diagram illustrating a system, in accordance with embodiments of the disclosure.

FIG. 5 is a simplified block diagram illustrating a system, in accordance with embodiments of the disclosure.

### DETAILED DESCRIPTION

It may be desirable to form RDLs (including RDLs of interposers and RDLs of dies) including routed conductive lines having relatively small dimensions (e.g., horizontal width and/or vertical height). RDLs may be formed using processes that generate routed conductive lines of having desirable dimensions (e.g., a desirable width, a desirable height). It may be advantageous for an RDL to have relatively small dimensions to minimize a footprint thereof within a device and/or to enhance performance (e.g., signal transmission speed) of the device.

Conventional smaller routed conductive lines may exhibit higher electrical resistance than conventional larger routed conductive lines, which may be undesirable for some applications.

Various embodiments of the disclosure include RDLs including routed conductive lines that are relatively small and that exhibit relatively low electrical resistances (e.g., electrical resistance below an electrical-resistance threshold) as compared to conventional RDLs including relatively small routed conductive lines. Further, configurations of the disclosure facilitate capacitance below a capacitance threshold.

Device configurations of the disclosure may include RDLs including routed conductive lines, each of the routed conductive lines including multiple traces extending substantially in parallel. An individual routed conductive line may extend between a first location and a second location, and may include two or more traces extending substantially in parallel between the first location and the second location. In some embodiments, the two or more traces are stacked in respective layers of the RDLs. For example, the two or more traces may be stacked, one above another, in respective layers of the RDLs. In such embodiments, the two or more traces are coupled by conductive vias. One of the conductive vias may be at the first location and another of the conductive vias may be at the second location. In additional embodiments, the two or more traces are arranged side-by-side in a layer of the RDLs. In such embodiments, the two or more traces are coupled by coupling traces. One of the coupling traces may be at the first location and another of the coupling traces may be at the second location. In further embodiments, the two or more or more traces include traces arranged side-by-side, stacked in multiple respective layers of the RDLs. For example, the two or more traces may include a first trace and a second trace arranged side-by-side in a first layer of the redistribution layers; and a third trace and a fourth trace arranged side-by-side in a second layer of the redistribution layers. The third trace may be under the first trace, and the fourth trace may be under the second trace. Such embodiments include conductive vias and coupling traces to couple the two or more traces (e.g., at the first location and at the second location).

Each of the traces of an individual routed conductive line may have desirable dimensions (e.g., a desirable horizontal width and/or a desirable vertical height). The desirable trace dimensions may be facilitated through methods of the disclosure. For example, individual traces of a routed conductive line, according to examples disclosed herein, may be within the desirable trace dimensions (in width and/or height) and yet the routed conductive line as a whole may exhibit resistance below an electrical-resistance threshold because all of the traces are electrically in parallel.

Each of the traces, considered individually, may be relatively small and/or may exhibit an electrical resistance above an electrical resistance threshold. Because all of the traces are electrically in parallel between the first location and the second location, all of the traces, considered collectively, may exhibit an electrical resistance lower than the electrical-resistance threshold.

In some embodiments, the traces are arranged, relative to ground lines, such that the routed conductive lines exhibit capacitance below a capacitance threshold.

Some embodiments may allow signal transmission at high speeds, for example, 8 gigabits per second or higher. Some embodiments may be suitable for single-ended signaling or differential signaling.

Some embodiments exhibit lower insertion loss compared with conventional routed conductive lines. Some embodiments may exhibit a higher voltage swing in a pulse response than conventional routed conductive lines.

Some embodiments may be applicable to high-bandwidth memory (HBM). For example, some interposer embodiments may be used in, or with, HBM.

Although various embodiments are described herein with reference to interposers and on-die routing, the disclosure is not so limited, and the embodiments may be generally applicable to electronic systems and/or microelectronic devices including interconnect solutions, e.g., RDLs. Examples where embodiments may be used include embedded multi-die interconnect bridges (EMID), package routing, printed-circuit board routing, and/or any application in which it may be desirable to decrease resistance of routing lines. Embodiments of the disclosure will now be described with reference to the accompanying drawings.

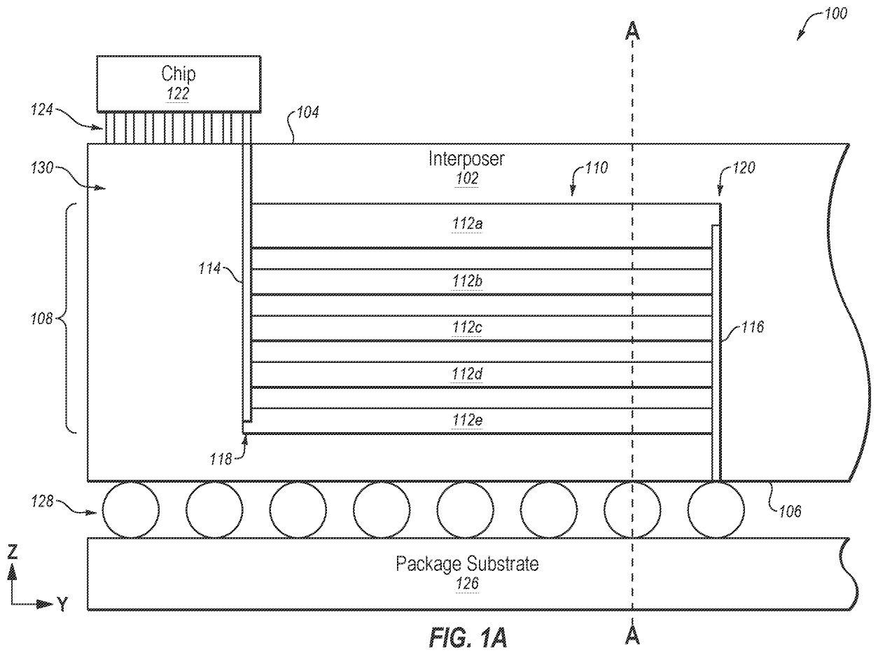

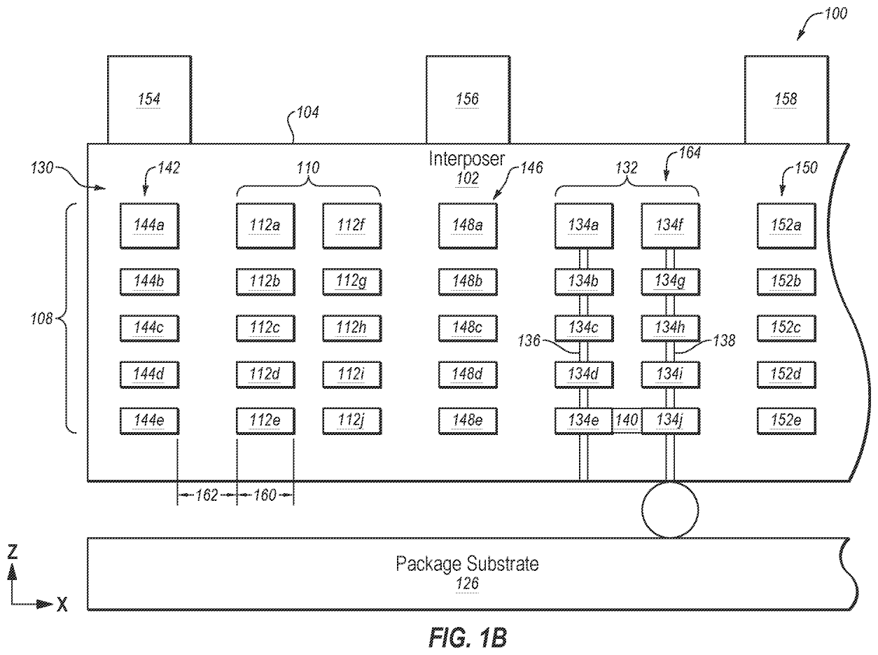

FIG. 1A is a simplified, schematic, side, sectional, elevation view of a device 100 (e.g., a microelectronic device, a semiconductor device, a memory device), in accordance with embodiments of the disclosure. Device 100 includes an interposer 102 including redistribution layers 108. Redistribution layers 108 include a routed conductive line 110. Routed conductive line 110 may include trace 112a, trace 112b, trace 112c, trace 112d, and trace 112e (which may be collectively referred to as “traces 112”). Routed conductive line 110 may exhibit electrical resistance below an electrical-resistance threshold, even if each of traces 112, considered individually, have dimensions (e.g., a horizontal width and/or a vertical height) that would cause each of traces 112, considered individually, to exhibit electrical resistance greater than the electrical-resistance threshold.

Device 100 may include a chip 122, a package substrate 126, and an interposer 102 between and electrically coupling the package substrate 126 and the chip 122. Interposer 102 may include redistribution layers 108 including routed conductive lines. Routed conductive line 110 is an example of one of the routed conductive lines of redistribution layers 108. Routed conductive line 110 may horizontally extend (e.g., in a direction parallel to the Y-axis) between a first location 118 and a second location 120. Routed conductive line 110 may include two or more traces 112 extending substantially in parallel between first location 118 and second location 120.

Interposer 102 may include an upper surface 104 for coupling to chip 122 and a lower surface for coupling to package substrate 126. Interposer 102 may include bond pads on upper surface 104 and/or on lower surface 106. Interposer 102 may electrically couple chip 122 to package substrate 126. For example, interposer 102 may include respective routed conductive lines between one or more of connections 124 of chip 122 and a corresponding one or more of connections 128 of package substrate 126. Connections 124 may be microbumps, for example. Connections 128 may be C4 bumps, for example. Connections 124 may exhibit a smaller pitch (e.g., spacing between connections 124) than a pitch of connections 128. Interposer 102 may be a FOWLP. Additionally or alternatively, interposer 102 may electrically couple multiple chips together, and/or to package substrate 126.

Chip 122 may be any suitable chip including, for example, an application-specific integrated circuit (ASIC), a memory chip or a processor chip.

Package substrate 126 may be any suitable substrate, for example, a printed circuit board, or an organic substrate.

Interposer 102 may include redistribution layers 108. Redistribution layers 108 may include multiple routed conductive lines (including routed conductive line 110) arranged in bulk substrate 130. Redistribution layers 108 may include multiple layers, with some layers including bulk substrate 130 and other layers including routed conductive lines arranged in bulk substrate 130. Redistribution layers 108 may include any quantity of layers.

In some embodiments, bulk substrate 130 is formed of and includes insulative material, such as dielectric oxide material (e.g., silicon oxide material, such as silicon dioxide (SiO₂). In additional embodiments, bulk substrate 130 is formed of and includes organic compound material, such as polymeric material (e.g., polyethylene terephthalate (PET), polycarbonate (PC)) or a laminated PCB material, e.g., FR4.

Interposer 102 may include any quantity of routed conductive lines. The routed conductive lines may include portions that extend in a direction parallel to the X-axis, and portions that extend in a direction parallel to the Y-axis, as illustrated in FIG. 1A. Routed conductive line 110 is an example of one of the routed conductive lines, and extends parallel to the Y-axis, between first location 118 and second location 120. As used herein, the term “parallel” means substantially parallel.

Routed conductive line 110 includes five traces 112 in the Y-Z plane illustrated in FIG. 1A for descriptive purposes. Any of the routed conductive lines of redistribution layers 108 may include any quantity of traces. In FIG. 1A, trace 112a has a height that is greater than a height of the others of traces 112, as an example and for descriptive purposes to illustrate that traces 112 need not have substantially the same dimensions as one another. For example, according to a process used to form redistribution layers 108, one or more of traces 112 (e.g., trace 112a) may have a vertical height in a direction parallel to the Z-axis that is greater than one or more vertical heights of individual others of traces 112.

Routed conductive line 110 may include a conductive via 114 at first location 118 to couple traces 112 to one another at first location 118. Routed conductive line 110 may include an additional conductive via 116 at second location 120 to couple traces 112 to one another at second location 120. Conductive via 114 may terminate at a bond pad on upper surface 104, e.g., to couple to one or more of connections 124 of chip 122. Conductive via 116 may terminate at a bond pad on lower surface 106, e.g., to couple to one or more of connections 128 of package substrate 126.

Any of the routed conductive lines may include any number of conductive vias between terminal points of the respective routed conductive line. For example, routed conductive line 110 may include one or more conductive vias between first location 118 and second location 120.

FIG. 1B is a schematic, sectional, elevation view of the device shown in FIG. 1A, along a section line A-A shown in FIG. 1A. The view of FIG. 1B is transverse to the view of FIG. 1A.

Routed conductive line 110 may include trace 112a, trace 112b, trace 112c, trace 112d, and trace 112e stacked, one above another, in the Y-Z plane illustrated by FIG. 1A. Additionally, routed conductive line 110 may include trace 112f, trace 112g, trace 112h, trace 112i, and trace 112j, e.g., stacked one above another in a Y-Z plane arranged beside the Y-Z plane illustrated by FIG. 1A. Trace 112f may arranged side-by-side, and substantially in parallel, with trace 112a in a layer of redistribution layers 108. Trace 112g may arranged side-by-side, and substantially in parallel, with trace 112b in a layer of redistribution layers 108. Trace 112h may arranged side-by-side, and substantially in parallel, with trace 112c in a layer of redistribution layers 108. Trace 112i may arranged side-by-side, and substantially in parallel, with trace 112d in a layer of redistribution layers 108. Trace 112j may arranged side-by-side, and substantially in parallel, with trace 112e in a layer of redistribution layers 108.

Additionally, device 100 may include routed conductive line 132, which is another example routed conductive line of redistribution layers 108. Routed conductive line 132 may include trace 134a, trace 134b, trace 134c, trace 134d, trace 134e, trace 134e, trace 134f, trace 134g, trace 134h, trace 134i, and trace 134j (which may be referred to collectively as “traces 134”). Routed conductive line 132 (including traces 134) may be the same as, may be substantially similar to, and/or perform the same functions as, routed conductive line 110 (including traces 112). Routed conductive line 132 and routed conductive line 110 may be located at different horizontal positions (e.g., in a direction parallel to the X-axis) than one another. For example, routed conductive line 110 may extend between first location 118 and second location 120; and routed conductive line 132 may extend between a third location and a fourth location 164.

Routed conductive line 132 may include a conductive via 136 coupling trace 134a, trace 134b, trace 134c, trace 134d, and trace 134e to one another. Routed conductive line 132 may also include an additional conductive via 138 coupling trace 134f, trace 134g, trace 134h, trace 134i, and trace 134j to one another. Routed conductive line 132 may additionally include a coupling trace 140 coupling trace 134a, trace 134b, trace 134c, trace 134d, and trace 134e to trace 134f, trace 134g, trace 134h, trace 134i, and trace 134j. Coupling trace 140 may be in the same layer as one or more of trace 134a and trace 134f, trace 134b and trace 134g, trace 134c and trace 134h, trace 134d and trace 134i, and trace 134e and trace 134j. Routed conductive line 132 may include additional coupling traces in the same layer as one or more of trace 134a and trace 134f, trace 134b and trace 134g, trace 134c and trace 134h, and trace 134d and trace 134i.

Routed conductive lines of redistribution layers 108 may include routed conductive lines configured to carry signals. Such routed conductive lines may be referred to herein as “signaling lines.” For example, routed conductive line 110 and routed conductive line 132 may be signaling lines configured to carry signals between connections of interposer 102.

Additionally, the routed conductive lines of redistribution layers 108 may include routed conductive lines configured to carry power and/or ground/bias. Such routed conductive lines may be referred to herein as “ground lines.” The ground lines may be the same as, may be substantially similar to, and/or perform the same functions as, the signaling lines. Interposer 102 may include ground lines in redistribution layers 108 e.g., ground line 142, ground line 146, and ground line 150. Interposer 102 may include ground lines on upper surface 104 (e.g., ground line 154, ground line 156, and ground line 158), and/or on lower surface 106.

Each of the ground lines may include respective ground traces. For example, each of ground line 142, ground line 146, and ground line 150 may include respective ground traces. Ground line 142 may include ground trace 144a, ground trace 144b, ground trace 144c, ground trace 144d, and ground trace 144e (which may be referred to collectively as “ground traces 144”). Ground line 146 may include ground trace 148a, ground trace 148b, ground trace 148c, ground trace 148d, and ground trace 148e. Ground line 150 may include ground trace 152a, ground trace 152b, ground trace 152c, ground trace 152d, and ground trace 152e. Ground traces of respective ground lines may be coupled by conductive vias (e.g., similar to conductive via 136 and conductive via 138) and/or by coupling traces (e.g., similar to coupling trace 140). Respective ground traces (e.g., of ground line 142, ground line 146, and ground line 150) may be in the same layers of redistribution layers 108 as respective traces of signaling lines (e.g., routed conductive line 110 and/or routed conductive line 132).

Routed conductive lines of redistribution layers 108 may be arranged such that no routed conductive line extends, for a distance greater than a horizontal width of routed conductive line, parallel to and above any of other of routed conductive line. For example, some of routed conductive lines may pass over or under others of routed conductive lines (e.g., at a location where a first routed conductive line of routed conductive lines extends in a direction parallel to the Y-axis and a second routed conductive line of routed conductive lines extends in a direction parallel to the X-axis), but none of routed conductive lines may extend in parallel, one above, and within a horizontal area of, another.

A routed conductive line vertically offset from (e.g., above or below) and within a horizontal area of another routed conductive line may cause the routed conductive lines to exhibit capacitance, e.g., based on a voltage differential between the routed conductive lines and the proximity between the routed conductive lines. By not including routed conductive lines vertically offset from others of routed conductive lines, redistribution layers 108 may cause each routed conductive line thereof to exhibit capacitance below a capacitance threshold. Traces in a stack of traces of an individual routed conductive line may not exhibit capacitance between the traces because all of the traces may be electrically coupled and may carry the same voltage at any given time.

Redistribution layers 108 may be free of ground lines vertically offset from (e.g., above or below) and within horizontal areas of signaling lines. For example, redistribution layers 108 may include bulk substrate 130 above and below signaling lines of the routed conductive lines of the redistribution layers 108. Additionally, interposer 102 may be free of ground lines on upper surface 104 or on lower surface 106 that are vertically offset from (e.g., above or below) and within horizontal areas of signaling lines. Additionally, redistribution layers 108 may be free of signaling lines extending in parallel vertically above and within horizontal areas of other signaling lines.

For example, interposer 102 may include ground line 154, ground line 156, and ground line 158 on upper surface 104 of interposer 102. Ground line 154 may be arranged to vertically overlie and horizontally overlap ground line 142, ground line 156 may be arranged to vertically overlie and horizontally overlap ground line 146, and ground line 158 may be arranged to vertically overlie and horizontally overlap ground line 150. The arrangement of ground line 154 to ground line 142, ground line 156 to ground line 146 and ground line 158 to ground line 150 may be such that ground lines are do not vertically overlie (or vertically underlie) and horizontally overlap signaling lines of redistribution layers 108.

Additionally, routed conductive lines of redistribution layers 108 may be arranged such that there is at least a threshold distance between routed conductive lines. Maintaining at least a threshold distance between routed conductive lines may cause each routed conductive line thereof to exhibit capacitance below a capacitance threshold.

For example, portions of ground lines may extend parallel to corresponding portions of signaling lines e.g., as illustrated by the cross-section of ground lines (including ground line 142, ground line 146, and ground line 150) and signaling lines (including routed conductive line 110 and routed conductive line 132) illustrated by the X-Z plane illustrated by FIG. 1B. Signaling lines and ground lines may be arranged to maintain a threshold distance (e.g., distance 162) between any ground line and any signaling line. Maintaining a threshold distance between ground lines and signaling lines may permit the capacitance of the signaling lines to be within a capacitance threshold.

Additionally, routed conductive lines of redistribution layers 108 may be arranged such that relatively wide faces of routed conductive lines do not face other routed conductive lines. For example, routed conductive lines may be arranged such that all wide faces of all of routed conductive lines face in a direction parallel to the Z-axis. Arranging routed conductive lines such that wide faces of routed conductive lines do not face other routed conductive lines may limit broadside capacitive coupling between routed conductive lines.

For example, signaling lines and ground lines may be arranged with respective wide faces of traces of signaling lines facing 90 degrees away from traces of ground lines, and wide faces of the ground lines facing 90 degrees away from traces of signaling lines. For example, wide faces of traces 112 of routed conductive line 110 may face in a direction parallel to the Z-axis, e.g., 90 degrees away from ground traces 144 of ground line 142.

Routed conductive lines (e.g., routed conductive line 110 and routed conductive line 132, and/or ground line 142, ground line 146, and ground line 150) may be configured to exhibit an electrical resistance below an electrical-resistance threshold, a capacitance below a capacitance threshold, a predetermined electrical resistance, and/or a predetermined capacitance. In particular, one or more of a horizontal width (e.g., horizontal width 160) of individual traces, a count of traces, an arrangement of traces, and a distance between traces and ground traces may be configured to cause routed conductive lines to exhibit respective electrical resistances below an electrical-resistance threshold, respective capacitances below a capacitance threshold, respective predetermined electrical resistances, and/or respective predetermined capacitances.

In some embodiments, a vertical height of traces is selected according to a process to be used to generate the traces. In some embodiments, a horizontal width (e.g., horizontal width 160) of traces of a routed conductive line are selected, at least in part, based on the process used to generate the traces. In some embodiments, a horizontal width (e.g., horizontal width 160) of traces of a routed conductive line are selected to cause routed conductive lines to exhibit an electrical resistance below an electrical-resistance threshold, a capacitance below a capacitance threshold, a predetermined electrical resistance, and/or a predetermined capacitance.

In some embodiments, a quantity (e.g., count, number) of traces of a routed conductive line is selected to cause the routed conductive lines to exhibit an electrical resistance below an electrical-resistance threshold, a capacitance below a capacitance threshold, a predetermined electrical resistance, and/or a predetermined capacitance. For example, in FIG. 1B, routed conductive line 110 is illustrated as including ten (10) traces 112. A quantity of traces 112 may be selected to cause routed conductive line 110 to exhibit an electrical resistance below a resistance threshold or a predetermined electrical resistance.

In some embodiments, an arrangement of traces of a routed conductive line is selected to cause the routed conductive lines to exhibit an electrical resistance below an electrical-resistance threshold, a capacitance below a capacitance threshold, a predetermined electrical resistance, and/or a predetermined capacitance. For example, in FIG. 1B, routed conductive line 110 is illustrated as including ten (10) traces 112 in two (2) stacks of five (5) traces each. The arrangement of traces 112 (in two (2) stacks of five (5) traces each) may have been selected to cause routed conductive line 110 to exhibit a capacitance below a capacitance threshold or a predetermined capacitance.

In some embodiments, distance between traces of a routed conductive line and traces of a ground line are selected to cause the routed conductive lines to exhibit an electrical resistance below an electrical-resistance threshold, a capacitance below a capacitance threshold, a predetermined electrical resistance, and/or a predetermined capacitance. For example, in FIG. 1B, traces 112 of routed conductive line 110 are illustrated as being distance 162 from ground traces 144 of ground line 142. Distance 162 may be selected to cause routed conductive line 110 to exhibit a capacitance below a capacitance threshold, or a predetermined capacitance.

The configuration of routed conductive lines of redistribution layers 108 of device 100, including dimensions of traces, quantities of traces, arrangements of traces, and distances between traces and ground traces may permit the routed conductive lines to exhibit electrical resistances and/or capacitances below respective electrical resistance and capacitance thresholds, e.g., even when a vertical height of traces (e.g., which may be dependent on a process, such as a process used to form interposer 102) is short (e.g., short enough that an individual trace would exhibit an electrical resistance exceeding the electrical-resistance threshold).

A configuration of routed conductive lines, including dimensions of traces, quantities of traces, arrangements of traces, and distances between traces and ground traces may permit the routed conductive lines to exhibit predetermined respective electrical resistances and/or capacitances. The electrical resistance and capacitance of a routed conductive line may be selected to govern a frequency response of routed conductive lines to signals conducted by routed conductive lines.

For example, a predetermined electrical resistance and a predetermined capacitance of a routed conductive line may be selected to cause the routed conductive line to operate as a filter, e.g., a low-pass filter, when the routed conductive line conducts signals. The predetermined electrical resistance may include a range of electrical resistances. The predetermined capacitance may include a range of capacitances. Accordingly, embodiments of the disclosure allow routed conductive lines to operate to conduct signals and to filter the signals, e.g., to remove high-frequency noise.

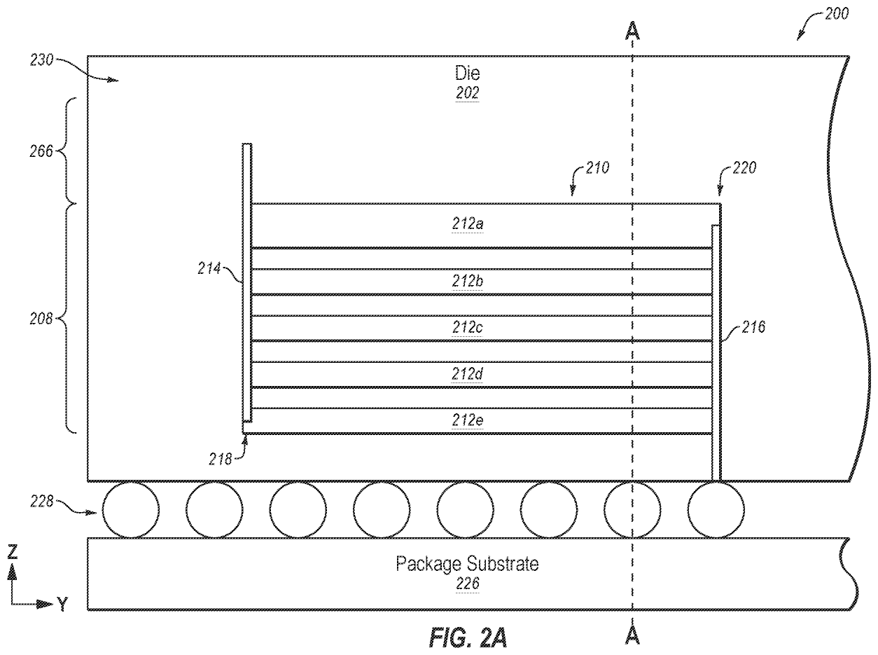

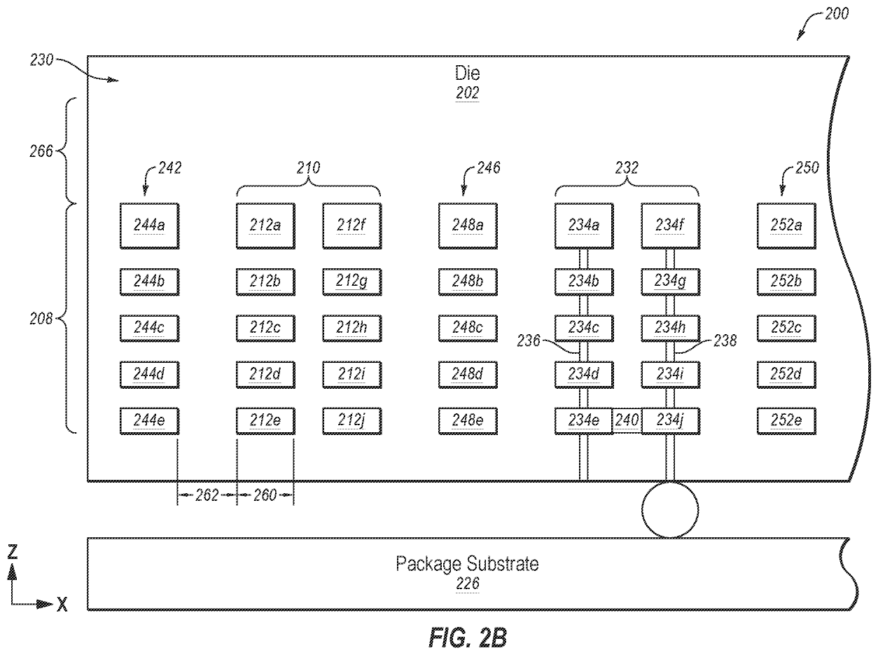

FIG. 2A is a simplified, schematic, side, sectional, elevation view of a device 200, in accordance with embodiments of the disclosure. FIG. 2B is a schematic, sectional, elevation view of the device shown in FIG. 2A, along a section line A-A shown in FIG. 2A. The view of FIG. 2B is transverse to the view of FIG. 2A.

Device 200 includes a die 202. Die 202 includes redistribution layers 208. Redistribution layers 208 may be the same as, may be substantially similar to, and/or perform the same functions as, redistribution layers 108 of device 100 previously described herein with reference to FIG. 1A and FIG. 1B. Device 100 (FIG. 1A and FIG. 1B) illustrates an embodiment of the disclosure, in the context of an interposer 102; and device 200 (FIG. 2A and FIG. 2B) illustrates an embodiment of the disclosure in the context of on-die routing within die 202.

Referring collectively to FIG. 2A and FIG. 2B, redistribution layers 208 include routed conductive lines, including, as examples, routed conductive line 210 and routed conductive line 232. The routed conductive lines of device 200 may be the same as, may be substantially similar to, and/or perform the same functions as, the routed conductive lines of device 100 previously described herein with reference to FIG. 1A and FIG. 1B (including routed conductive line 110 and routed conductive line 132).

For example, routed conductive line 210 includes traces 212 (including trace 212a, trace 212b, trace 212c, trace 212d, and trace 212e). Traces 212 may be the same as, may be substantially similar to, and/or perform the same functions as, traces 112 of device 100 previously described herein with reference to FIG. 1A and FIG. 1B. Routed conductive line 210 includes conductive via 214 and conductive via 216. Conductive via 214 and conductive via 216 may be same as, may be substantially similar to, and/or perform the same functions as, conductive via 114 and conductive via 116 of device 100 previously described herein with reference to FIG. 1A and FIG. 1B.

Routed conductive line 210 extends from first location 218 to second location 220, which first location 218 and second location 220 may be the same as, from the functional perspective of routed conductive line 210, first location 118 and second location 220 of device 100 previously described herein with reference to FIG. 1A and FIG. 1B. Routed conductive line 210 may couple features (e.g., structures, materials, devices, regions) of logic levels 266 (e.g., logic tiers) at first location 218 with connections 228, which connections 228 may provide for connections from die 202 to other devices, e.g., to package substrate 226. Alternatively, routed conductive line 210 may couple features of logic levels 266 at first location 218 with features of logic levels 266 at second location 220.

Die 202 includes bulk substrate 230, which bulk substrate 230 may be the same as, may be substantially similar to, and/or perform the same functions as, bulk substrate 130 of device 100 previously described herein with reference to FIG. 1A and FIG. 1B.

Redistribution layers 208 includes routed conductive line 232, including trace 234a, trace 234b, trace 234c, trace 234d, trace 234e, trace 234f, trace 234g, trace 234h, trace 234i, and trace 234j (which may be referred to collectively as “traces 234”). Routed conductive line 232, including traces 234, may be the same as, may be substantially similar to, and/or perform the same functions as, routed conductive line 132, including traces 134, of device 100 previously described herein with reference to FIG. 1A and FIG. 1B. Conductive via 236, conductive via 238, and coupling trace 240 may be the same as, may be substantially similar to, and/or perform the same functions as, conductive via 136, conductive via 138, and coupling trace 140 respectively, of device 100 previously described herein with reference to FIG. 1A and FIG. 1B.

Routed conductive lines of redistribution layers 208 include ground lines, including as examples, ground line 242, ground line 246, and ground line 250. Ground lines of device 200 (including ground line 242, ground line 246, and ground line 250) may be the same as, may be substantially similar to, and/or perform the same functions as, the ground lines of device 100 previously described herein with reference to FIG. 1A and FIG. 1B (including ground line 142, ground line 146, and ground line 150). Additionally, ground trace 244a, ground trace 244b, ground trace 244c, ground trace 244d, and ground trace 244e (which may be referred to collectively as “ground traces 244”) of ground line 242, ground trace 248a, ground trace 248b, ground trace 248c, ground trace 248d, and ground trace 248e of ground line 246, and ground trace 252a, ground trace 252b, ground trace 252c, ground trace 252d, and ground trace 252e may be same as, may be substantially similar to, and/or perform the same functions as, ground traces 144 of ground line 142 of device 100 previously described herein with reference to FIG. 1A and FIG. 1B.

Routed conductive lines of redistribution layers 208 exhibit a horizontal width 260 and a distance 262 between routed conductive lines and ground lines. Horizontal width 260, distance 262, a quantity of traces of routed conductive lines, and an arrangement of routed conductive lines may be configured (e.g., selected and generated) such that the routed conductive lines exhibit respective electrical resistances below an electrical-resistance threshold, respective capacitances below a capacitance threshold, respective predetermined electrical resistances, and/or respective predetermined capacitances.

Logic levels 266 of die 202 may include one or more vertical elevations including gates and/or conductive lines that may perform one or more operations related to, e.g., storing memory, or performing logical operations.

A configuration of routed conductive lines of redistribution layers 208 of device 200, including dimensions of traces, quantities of traces, arrangements of traces, and distances between traces and ground traces may permit routed conductive lines to exhibit electrical resistances and/or capacitances below respective electrical resistance and capacitance thresholds, e.g., even when a vertical height of traces (e.g., which may be dependent on a process used to form die 202) is relatively short (e.g., short enough that an individual trace would exhibit an electrical resistance exceeding the electrical-resistance threshold).

A configuration of routed conductive lines, including the dimensions of traces, quantities of traces, arrangements of traces, and distances between traces and ground traces may permit the routed conductive lines to exhibit predetermined respective electrical resistances and/or capacitances. An electrical resistance and a capacitance of a routed conductive line may be selected to govern a frequency response of the routed conductive lines to signals routed (e.g., carried, transmitted, relayed) by the routed conductive lines.

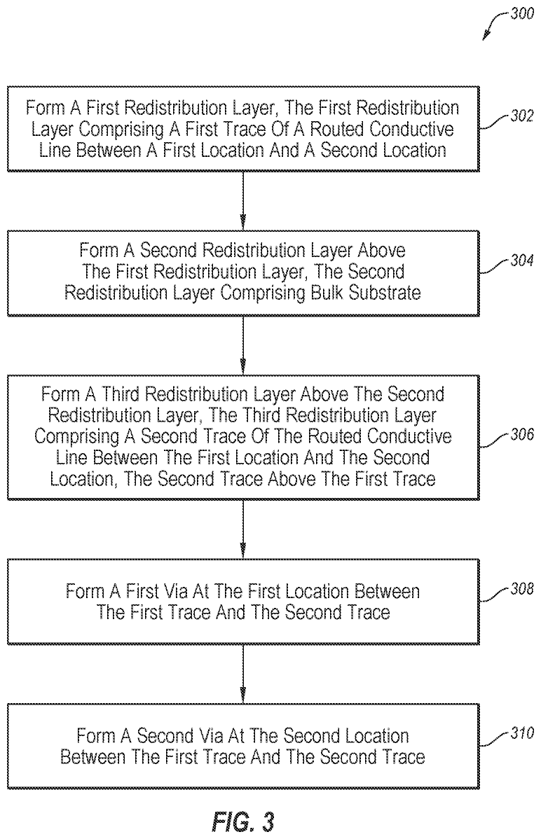

FIG. 3 is a flowchart illustrating a formation method 300, in accordance with embodiments of the disclosure. Method 300 may be performed to form one or more of a structure, a device, and a system of the disclosure, such as, without limitation, one or more of device 100 (FIG. 1A and FIG. 1B), interposer 102 (FIG. 1A and FIG. 1B), redistribution layers 108 (FIG. 1A and FIG. 1B), device 200 (FIG. 2A and FIG. 2B), die 202 (FIG. 2A and FIG. 2B), redistribution layers 208 (FIG. 2A and FIG. 2B), another structure, another device, and an electronic system. Although illustrated as discrete blocks, various blocks may be divided into additional blocks, combined into fewer blocks, or eliminated, depending on the desired implementation.

At block 302, a first redistribution layer may be formed. First redistribution layer may include a first trace of a routed conductive line between a first location and a second location. For example, a first redistribution layer of redistribution layers 108 of interposer 102 previously described herein with reference to FIG. 1A and FIG. 1B may be formed. First redistribution layer of redistribution layers 108 may include trace 112e previously described herein with reference to FIG. 1A and FIG. 1B between first location 118 and second location 120 previously described herein with reference to FIG. 1A and FIG. 1B. As another example, a first redistribution layer of redistribution layers 208 of die 202 previously described herein with reference to FIG. 2A and FIG. 2B may be formed. The first redistribution layer of redistribution layers 208 may include trace 212e previously described herein with reference to FIG. 2A and FIG. 2B between first location 218 and second location 220 previously described herein with reference to FIG. 2A and FIG. 2B.

In block 304, a second redistribution layer may be formed above first redistribution layer. Second redistribution layer may include bulk substrate. For example, a second redistribution layer of redistribution layers 108 of interposer 102 may be formed. Second redistribution layer may include bulk substrate 130 previously described herein with reference to FIG. 1A and FIG. 1B. As another example, a second redistribution layer of redistribution layers 208 of die 202 may be formed. The second redistribution layer may include bulk substrate 230 previously described herein with reference to FIG. 2A and FIG. 2B.

At block 306, a third redistribution layer may be formed above second redistribution layer. Third redistribution layer may include a second trace of routed conductive line between first location and second location. Second trace may be above first trace. For example, a third layer of redistribution layers 108 of interposer 102 may be formed. Third redistribution layer may include trace 112d previously described herein with reference to FIG. 1A and FIG. 1B between first location 118 and second location 120. Trace 112d may be above trace 112e. For example, a third layer of redistribution layers 208 of die 202 may be formed. Third redistribution layer may include trace 212d previously described herein with reference to FIG. 2A and FIG. 2B between first location 218 and second location 220. Trace 212d may be above trace 212e.

Method 300 may include forming any quantity of redistribution layers including bulk substrate or including traces of routed conductive lines. Method 300 may include forming any quantity of routed conductive lines between any quantity of respective locations. Method 300 may include forming multiple traces of the same and/or of different routed conductive lines (including signaling lines and/or ground lines) when forming first redistribution layer, second redistribution layer, and/or any quantity of redistribution layers.

At block 308, a first conductive via may be formed at first location between first trace and second trace. For example, conductive via 114 previously described herein with reference to FIG. 1A and FIG. 1B may be formed at first location 118. As another example, conductive via 214 previously described herein with reference to FIG. 2A and FIG. 2B may be formed at first location 218.

At block 310, a second via may be formed at second location between first trace and second trace. For example, conductive via 116 previously described herein with reference to FIG. 1A and FIG. 1B may be formed at second location 120. As another example, conductive via 216 previously described herein with reference to FIG. 2A and FIG. 2B may be formed at second location 220.

In some embodiments, method 300 includes selecting one or more of a horizontal width of first trace, a horizontal width of second trace, a quantity of additional traces of an individual routed conductive line, an arrangement of additional traces of an individual routed conductive line, a distance between first trace and a ground trace in first redistribution layer, and a distance between second trace and a ground trace in third redistribution layer, to cause an individual routed conductive line to exhibit an electrical resistance below an electrical-resistance threshold and/or a capacitance below a capacitance threshold. For example, horizontal width 160 of traces 112, a quantity of traces 112, an arrangement of traces 112, and/or distance 162 between traces 112 and ground traces 144 may be selected to cause routed conductive line 110 to exhibit an electrical resistance below an electrical-resistance threshold and/or a capacitance below a capacitance threshold. As another example, horizontal width 260 of traces 212, a quantity of traces 212, an arrangement of traces 212, and/or distance 262 between traces 212 and ground traces 244 may be selected to cause routed conductive line 110 to exhibit an electrical resistance below an electrical-resistance threshold and/or a capacitance below a capacitance threshold.

In some embodiments, method 300 includes selecting one or more of a horizontal width of first trace, a horizontal width of second trace, a count of additional traces of an individual routed conductive line, an arrangement of additional traces of an individual routed conductive line, a distance between first trace and a ground trace in a first redistribution layer, and a distance between second trace and a ground trace in a third redistribution layer, to cause an individual routed conductive line to exhibit a predetermined electrical resistance and a predetermined capacitance to govern a frequency response of an individual routed conductive line to signals routed (e.g., carried, relayed, transmitted, conducted) thereby. For example, horizontal width 160 of traces 112, a quantity of traces 112, an arrangement of traces 112, and/or distance 162 between traces 112 and ground traces 144 may be selected to cause routed conductive line 110 to exhibit a predetermined electrical resistance and a predetermined capacitance to govern a frequency response of routed conductive line 110 to signals routed (e.g., carried, relayed, transmitted, conducted) by routed conductive line 110. For example, horizontal width 260 of traces 212, a quantity of traces 212, an arrangement of traces 212, and/or distance 262 between traces 212 and ground traces 244 may be selected to cause routed conductive line 110 to exhibit a predetermined electrical resistance and a predetermined capacitance to govern a frequency response of routed conductive line 210 to signals routed (e.g., carried, relayed, transmitted, conducted) by routed conductive line 210.

Modifications, additions, or omissions may be made to method 300 without departing from the scope of the disclosure. For example, operations of method 300 may be implemented in differing order. Furthermore, the outlined operations and actions are only provided as examples, and some of the operations and actions may be optional, combined into fewer operations and actions, or expanded into additional operations and actions without detracting from the essence of the disclosed embodiment.

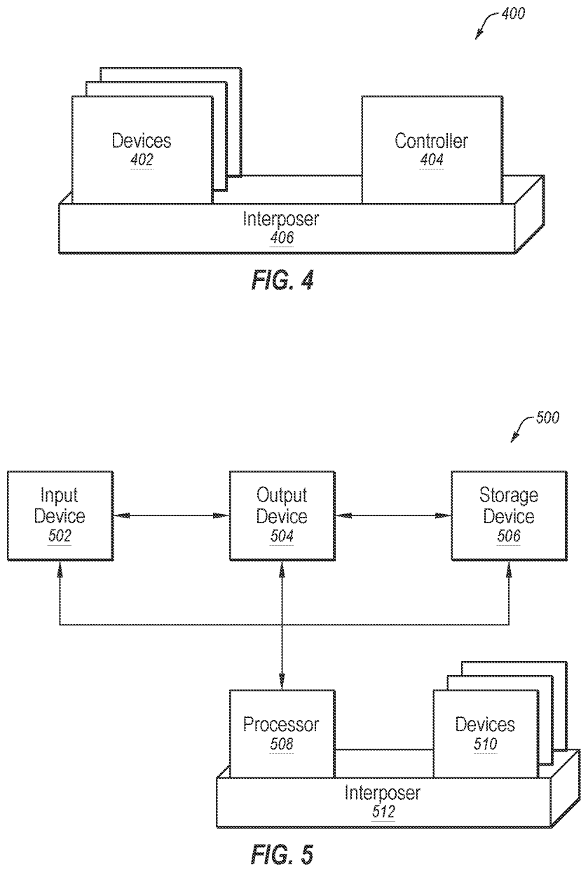

FIG. 4 is a simplified block diagram illustrating a system 400 (e.g., an electronic system), in accordance with embodiments of the disclosure. System 400, which may include, for example, a device (e.g., a microelectronic device, a semiconductor device, a memory device, a processor device), a quantity of devices 402, an interposer 406, and a controller 404. Controller 404 may be operatively coupled with devices 402 through interposer 406, so as to convey command and/or address signals to devices 402.

In some embodiments, at least one of devices 402 and/or controller 404 of system 400 is device 200 previously described herein with reference to FIG. 2A and FIG. 2B. For example, at least one of devices 402 and/or controller 404 may include redistribution layers 208 (FIG. 2A and FIG. 2B). Furthermore, in some embodiments, interposer 406 is interposer 102 previously described herein with reference to FIG. 1A and FIG. 1B.

FIG. 5 is a simplified block diagram illustrating a system 500 (e.g., an electronic system), in accordance with embodiments of the disclosure. System 500 includes at least one input device 502, which may include, for example, a keyboard, a mouse, or a touch screen. System 500 further includes at least one output device 504, such as a monitor, a touch screen, or a speaker. Input device 502 and output device 504 are not necessarily separable from one another. System 500 further includes a storage device 506. Input device 502, output device 504, and storage device 506 may be coupled to a processor 508. System 500 further includes a devices 510 coupled to processor 508 through interposer 512.

In some embodiments, at least one of devices 510 and/or processor 508 is device 200 previously described herein with reference to FIG. 2A and FIG. 2B. For example, at least one of devices 510 and/or processor 508 may include redistribution layers 208, in accordance with at least one embodiment of the disclosure. Furthermore, in some embodiments, interposer 512 is interposer 102 previously described herein with reference to FIG. 1A and FIG. 1B.

System 500 may include, for example, a computing, processing, industrial, or consumer product. For example, without limitation, system 500 may include a personal computer or computer hardware component, a server or other networking hardware component, a database engine, an intrusion prevention system, a handheld device, a tablet computer, an electronic notebook, a camera, a phone, a music player, a wireless device, a display, a chip set, a game, a vehicle, or other known systems.

Some embodiments include an interposer. The interposer includes an upper surface for coupling to a chip, a lower surface for coupling to a package substrate, and redistribution layers between the upper surface and the lower surface and including routed conductive lines. A respective one of the routed conductive lines extend between a first location and a second location and includes two or more traces extending substantially in parallel between the first location and the second location.

Some embodiments include a device. The device includes a chip, a package substrate, and an interposer between and electrically coupling the package substrate and the chip. The interposer includes redistribution layers. The redistribution layers include routed conductive lines. A respective one of the routed conductive lines extends between a first location and a second location and includes two or more traces extending substantially in parallel between the first location and the second location.

Some embodiments include a method. The method includes forming a first redistribution layer. The first redistribution layer includes a first trace of a routed conductive line between a first location and a second location. The method includes forming a second redistribution layer above the first redistribution layer. The second redistribution layer includes bulk substrate. The method includes forming a third redistribution layer above the second redistribution layer. The third redistribution layer includes a second trace of the routed conductive line between the first location and the second location, the second trace above the first trace. The method includes forming a first conductive via at the first location between the first trace and the second trace. The method includes forming a second conductive via at the second location between the first trace and the second trace.

Some embodiments include redistribution layers for routing signals within the die and including routed conductive lines. A respective one of the routed conductive lines extends between a first location and a second location and comprises two or more traces extending substantially in parallel between the first location and the second location.

In accordance with common practice, the various features illustrated in the drawings may not be drawn to scale. The illustrations presented in the disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, and/or flipped) and the spatially relative descriptors used herein interpreted accordingly.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the phrase “coupled to” refers to structures operatively connected with each other, such as electrically connected through a direct Ohmic connection or through an indirect connection (e.g., by way of another structure).

As used herein, the term “configured” refers to a size, shape, material composition, orientation, and arrangement of one or more of at least one structure and at least one apparatus facilitating operation of one or more of the structure and the apparatus in a pre-determined way.

As used herein, the term “device” or “memory device” may include a device with memory functionality, but not necessary limited to memory functionality. For example, a device or a memory device may include memory, a processor, and/or other components or functionalities. By way of non-limiting example only, the terms “device” and “memory device” include not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “semiconductor device” should be broadly construed, unless otherwise specified, to include microelectronic devices and MEMS devices that may or may not employ semiconductor functionality for operation (e.g., magnetic memory, optical devices, etc.).

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Jr), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. As used herein, “and/or” includes any and all combinations of one or more of the associated listed items.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms “first,” “second,” “third,” etc., connote a specific number of elements, these terms should not be understood to connote a specific number of elements.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternative useful combinations of the elements described, will become apparent to those skilled in the art from the description. Such modifications and embodiments also fall within the scope of the appended claims and equivalents.

What is claimed is:

1. An interposer, comprising:
an upper surface for coupling to a chip;
a lower surface for coupling to a package substrate; and
redistribution layers between the upper surface and the lower surface and comprising routed conductive lines, a respective one of the routed conductive lines extending between a first location and a second location and comprising two or more traces extending substantially in parallel between the first location and the second location.

2. The interposer of claim 1, wherein the two or more traces are stacked in respective layers of the redistribution layers.

3. The interposer of claim 2, wherein the redistribution layers comprise:
a first conductive via at the first location to couple the two or more traces at the first location; and
a second conductive via at the second location to couple the two or more traces at the second location.

4. The interposer of claim 1, wherein the two or more traces are arranged side-by-side in a layer of the redistribution layers.

5. The interposer of claim 4, wherein the respective one of the routed conductive lines further comprises a first coupling trace to couple the two or more traces at the first location and a second coupling trace to couple the two or more traces at the second location.

6. The interposer of claim 1, wherein the two or more traces comprise:
a first trace and a second trace arranged side-by-side in a first layer of the redistribution layers; and
a third trace and a fourth trace arranged side-by-side in a second layer of the redistribution layers, the third trace under the first trace and the fourth trace under the second trace.

7. The interposer of claim 6, wherein the redistribution layers comprise:
a first coupling trace to couple the first trace and the second trace at the first location;
a second coupling trace to couple the first trace and the second trace at the second location;
a first conductive via to couple the first trace and the third trace at the first location;
a second conductive via to couple the second trace and the fourth trace at the first location;
a third conductive via to couple the first trace and the third trace at the second location; and
a fourth conductive via to couple the second trace and the fourth trace at the second location.

8. The interposer of claim 1, wherein the respective one of the routed conductive lines comprises a signaling line, and wherein the routed conductive lines further comprise a ground line extending adjacent to the signaling line.

9. The interposer of claim 8, wherein the ground line comprises two or more ground traces extending substantially in parallel.

10. The interposer of claim 9, wherein:
a first redistribution layer of the redistribution layers comprises a first trace of the two or more traces and a first ground trace of the two or more ground traces; and
a second redistribution layer of the redistribution layers comprises a second trace of the two or more traces and a second ground trace of the two or more ground traces.

11. The interposer of claim 1, wherein the redistribution layers comprise bulk substrate between the two or more traces and the upper surface and between the two or more traces and the lower surface.

12. The interposer of claim 1, wherein the routed conductive lines of the redistribution layers are arranged in a bulk substrate, the bulk substrate comprising silicon dioxide.

13. The interposer of claim 1, wherein the routed conductive lines of the redistribution layers are arranged in a bulk substrate, the bulk substrate comprising an organic compound.

14. The interposer of claim 1, wherein one or more of a width of the two or more traces, a count of the two or more traces, an arrangement of the two or more traces, and a distance between the two or more traces and a ground line of the routed conductive lines of the redistribution layers are configured to cause the respective one of the routed conductive lines to exhibit a resistance below a resistance threshold and a capacitance below a capacitance threshold.

15. The interposer of claim 1, wherein one or more of a width of the two or more traces, a count of the two or more traces, an arrangement of the two or more traces, and a distance between the two or more traces and a ground line of the routed conductive lines of the redistribution layers are configured to cause the respective one of the routed conductive lines to exhibit a predetermined resistance and a predetermined capacitance to govern a frequency response of the respective one of the routed conductive lines to signals conducted by the respective one of the routed conductive lines.

16. A device, comprising:
a chip;
a package substrate; and
an interposer between and electrically coupling the package substrate and the chip, the interposer comprising:
redistribution layers comprising routed conductive lines, a respective one of the routed conductive lines extending between a first location and a second location and comprising two or more traces extending substantially in parallel between the first location and the second location.

17. A method, comprising:
forming a first redistribution layer, the first redistribution layer comprising a first trace of a routed conductive line between a first location and a second location;
forming a second redistribution layer above the first redistribution layer, the second redistribution layer comprising bulk substrate;
forming a third redistribution layer above the second redistribution layer, the third redistribution layer comprising a second trace of the routed conductive line between the first location and the second location, the second trace above the first trace;
forming a first conductive via at the first location between the first trace and the second trace; and
forming a second conductive via at the second location between the first trace and the second trace.

18. The method of claim 17, further comprising selecting one or more of a width of the first trace, a width of the second trace, a count of additional traces of the routed conductive line, an arrangement of the additional traces of the routed conductive line, a distance between the first trace and a ground trace in the first redistribution layer, and a distance between the second trace and a ground trace in the third redistribution layer, to cause the routed conductive line to exhibit a resistance below a resistance threshold and a capacitance below a capacitance threshold.

19. The method of claim 17, further comprising selecting one or more of a width of the first trace, a width of the second trace, a count of additional traces of the routed conductive line, an arrangement of the additional traces of the routed conductive line, a distance between the first trace and a ground trace in the first redistribution layer, and a distance between the second trace and a ground trace in the third redistribution layer, to cause the routed conductive line to exhibit a predetermined resistance and a predetermined capacitance to govern a frequency response of the routed conductive line to signals conducted by the routed conductive line.

20. The method of claim 17, wherein:
the first redistribution layer comprises a first ground trace of a ground line, the first ground trace extending adjacent to the first trace; and
the third redistribution layer comprises a second ground trace of the ground line, the second ground trace extending adjacent to the second trace.
